(19) United States
(12) Patent Application Publication
(10) Pub. No.: US 2008/0061765 A1
(43) Pub. Date: Mar. 13, 2008

(54) Multi-Channel Digital Oscilloscope

(76) Inventors: Daniel Arnoux, Paris (FR); Axel Arnoux, Paris (FR); Francisque Pion, Paris (FR); Gilbert Knockaert, Paris (FR); Alexandre Ungerer, Paris (JP)

Correspondence Address: BLANK ROME LLP, 600 NEW HAMPSHIRE AVENUE, N.W., WASHINGTON, DC, 20037, US

(21) Appl. No.: 11/597,506

(22) PCT Filed: May 27, 2005
(86) PCT No.: PCT/FR05/01315

§ 371 Date: Sep. 12, 2007

(30) Foreign Application Priority Data
May 27, 2004 (FR) 0405749

(51) Int. Cl. G01R 13/02

(52) U.S. Cl. 324/76.39

(57) ABSTRACT

The invention relates to a multi-channel digital oscilloscope having a plurality of analog inputs, circuits for the analog processing of input signals, sampling and digitizing circuits, means for triggering and synchronizing different channels and electrical isolation means. The invention is characterized in that, for N channels, where N is greater than 1 and at least equal to the total number of channels, at least the sampling and digitizing circuits are located between the analog input and the isolation means.

The present invention relates to the field of multichannel digital oscilloscopes.

These digital oscilloscopes can consist of a piece of independent equipment comprising all the electronic and computing systems, as well as the display system. They can also consist of a card or a computer peripheral. In this case, a part of the signal processing and of the display will be carried out on a computer which this peripheral transforms into an oscilloscope or a logical analyzer. Such an oscilloscope is sometimes called a “DSO” (Digital Storage Oscilloscope).

The electrical input signals of each channel are digitized by an analogue-to-digital converter controlled by a clock or time base with a programmable period. An analogue-to-digital conversion is triggered on every pulse edge of the clock (for example), and the digital image of the input voltage is written in the “output” memory line of the input module. This data is then written in a line of the data memory.

The data are written in the memory. When the “trigger conditions” are met, the entry continues until the data that correspond to these conditions are found in the memory zone selected by a trigger circuit.

A part of the memory is displayed on a visual display unit, and scrolling functions make it possible to change the part of the signal displayed.

In order to allow an analysis of the electrical signals not referenced with regard to the potential of the frame, it is necessary to ensure electrical insulation. The analyzed signals are often complex signals, comprising a low-level component written over a high-voltage carrier signal. In order to allow a relevant analysis of these signals, it is essential for the insulation means not to add any detectable disturbance to the signals.

U.S. Pat. No. 5,517,514 suggests the creation of a circuit to amplify the broadband input signal of an oscilloscope, comprising:

an amplifier on a low-level path, which amplifies the voltage of the broadband input signal and transmits a part of this voltage ranging from a continuous component to a low-frequency part of this voltage by means of an optocoupler which forms the first part of an insulating barrier, to a signal-combining device,

an amplifier on a high-level path, which amplifies the voltage of the broadband input signal and transmits a part of this signal ranging from a low frequency to a high frequency by means of a primary winding of a transformer, which forms a second part of the insulating barrier, to a signal-combining device.

The signal-combining device includes the first and second secondary windings of the transformer receiving the part ranging from the continuous component to a low frequency and the part ranging from a low frequency to a high frequency of the amplified input signal voltage. The first and second secondary windings cooperate with the primary winding such as to produce a substantially nil magnetic flux network in the transformer in the range going from the continuous component to the high frequency of the voltage of the broadband output signal. The top and bottom cut-off frequencies, for the LF and HF frequencies respectively, overlap so that the signal-combining device produces a broadband output signal voltage that has a flat square-wave response.

This solution consisting of insulating the analogue pre-treatment of the input signals is indeed rational, and it corresponds to the natural approach of those skilled in the trade. It enables the use of insulation means according to standard operating modes, and the solution of the aforementioned invention makes it possible to respond in a satisfying manner to the bandwidth problem of the signals to be analyzed. Above all, this solution is imposed on those skilled in the trade, since it makes it possible subsequently to process the digitisation of the input signals, after the “insulation barrier”, in a standard manner.

This solution is not completely satisfactory since, regardless of the quality and performance of the insulation means, they introduce disturbances (noise, non-linearity) in the signal of each of the channels, as well as crosstalk between the signals of different channels.

In order to address this disadvantage, the invention relates, in its most general sense, to a multichannel digital oscilloscope, comprising a plurality of analogue inputs, circuits for analogue processing of input signals, sampling circuits, digitisation circuits, trigger means and means for synchronizing various channels and electrical insulation means, characterized in that, for N channels, N being greater than 1 and at most equal to the total number of channels, at least the sampling and digitisation circuits are situated between the analogue input and the insulation means.

According to a first variant, it comprises means for resynchronization of traces corresponding to the input signals comprising a master acquisition machine controlling each of the acquisition machines of the sampling circuits of each of the channels.

Said master acquisition machine is advantageously the acquisition machine of one of the channels.

Said master acquisition machine preferably comprises a main Time Base delivering a distributed time signal to each channel.

Optionally, said main Time Base is located after the insulation means (frame side) and delivers a sampling clock CLK_Ech to all the channels.

According to a first embodiment of the invention, said insulation means are made up of a set of transformers.

Said transformers advantageously comprise common mode rejection means, for example electromagnetic shielding or winding with a midpoint.

According to a second embodiment of the invention, said insulation means comprise optocouplers.

According to a third embodiment of the invention, said insulation means comprise a radio transceiver.

According to a fourth embodiment of the invention, said insulation means comprise Hall-effect or magnetoresistance magnetic insulators.

According to a variant, at least a part of the data exchanged between the frame and the channels is multiplexed.

According to another variant, said insulation means are a combination of the aforementioned means.

According to another variant, at least two channels comprise sampling and digitisation circuits made up of a time base, a threshold trigger circuit supplying the acquisition machine with a pulse edge that corresponds to the input signal passing a trigger threshold.

Said circuits advantageously also comprise a buffer for storing digitized signals, for example an analogue memory located between the sampling circuit and the digitisation circuit, a digital memory located between the digitisation circuit and the insulation means or a digital memory located after the insulation means.

Each channel preferably comprises a circuit for identifying and memorizing the clock period that corresponds to the trigger (photo-trig). This circuit supplies digital identification information of the clock period transmitted with the signal samples of the relevant channel.

According to a specific embodiment, the oscilloscope according to the invention also comprises, for each channel, a vernier circuit made up of a ramp generator performing a linear “time difference/voltage difference” conversation in order to supply information that is representative of the time interval between the trigger pulse edge and the clock pulse edge, said information being digitized and transmitted with the signal samples of the relevant channel.

It advantageously comprises resynchronization means receiving conditional information from at least one channel to supply a start cue to the master acquisition machine.

According to a preferred variant, the slave acquisition machines control the sampling while waiting for the signal to end acquisition from the master acquisition machine.

According to another advantageous variant, it comprises an independent power supply for each channel which is insulated and adjusted for supplying the circuits located upstream from the insulation means.

According to a variant, it comprises a processor that controls the configuration of the circuits and acquisition machines according to settings chosen by the user, assuring the processing of the data of each channel as well as the service information, in order to calculate a graphic representation according to the signals acquired on the various channels.

The present invention will be understood better after reading the following description, relating to a non-limiting example of embodiment, referring to the appended drawings, in which:

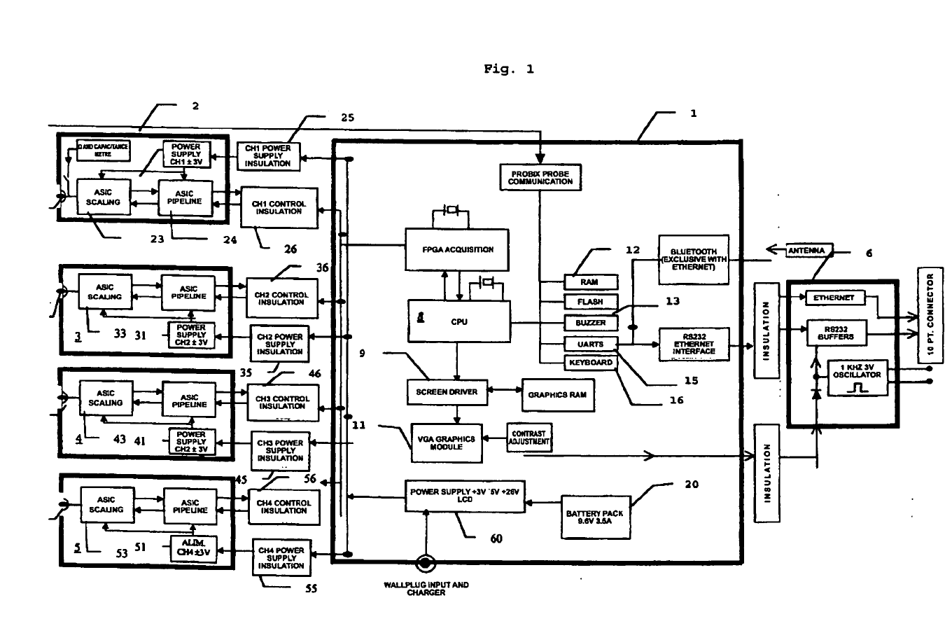

FIG. 1 shows a diagrammatic view of an oscilloscope according to the invention,

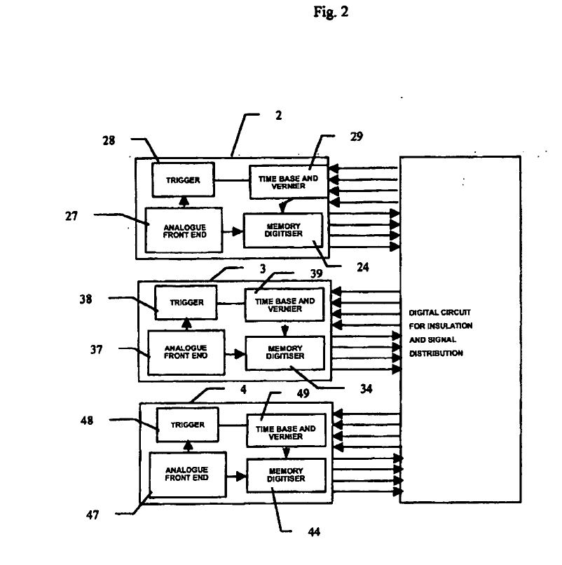

FIG. 2 shows a view of the input circuits (only three channels are shown),

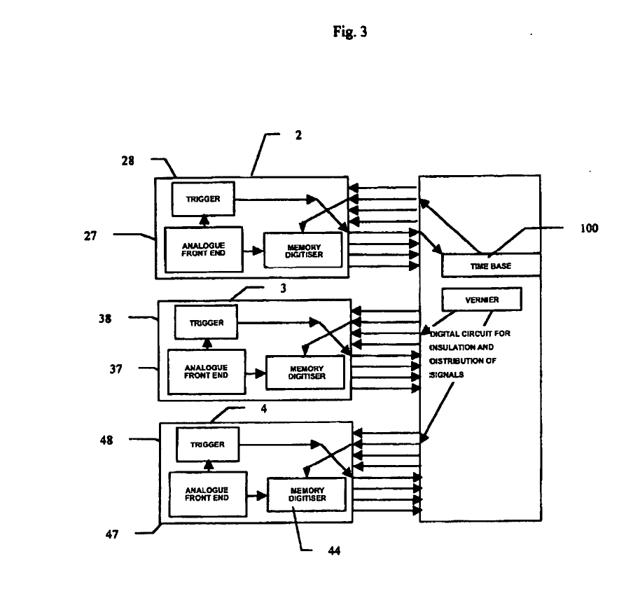

FIG. 3 shows a diagrammatic view of an alternative embodiment of the signal-acquisition circuits in which the time base block 100 is located in the potential of the frame.

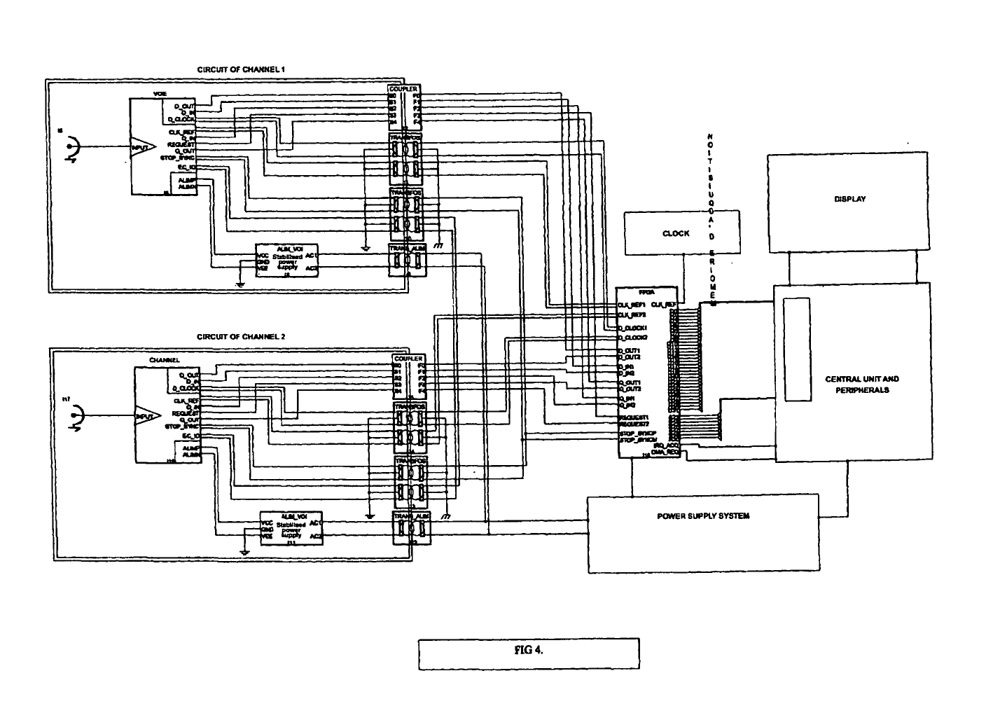

FIG. 4 shows a view of the acquisition machine,

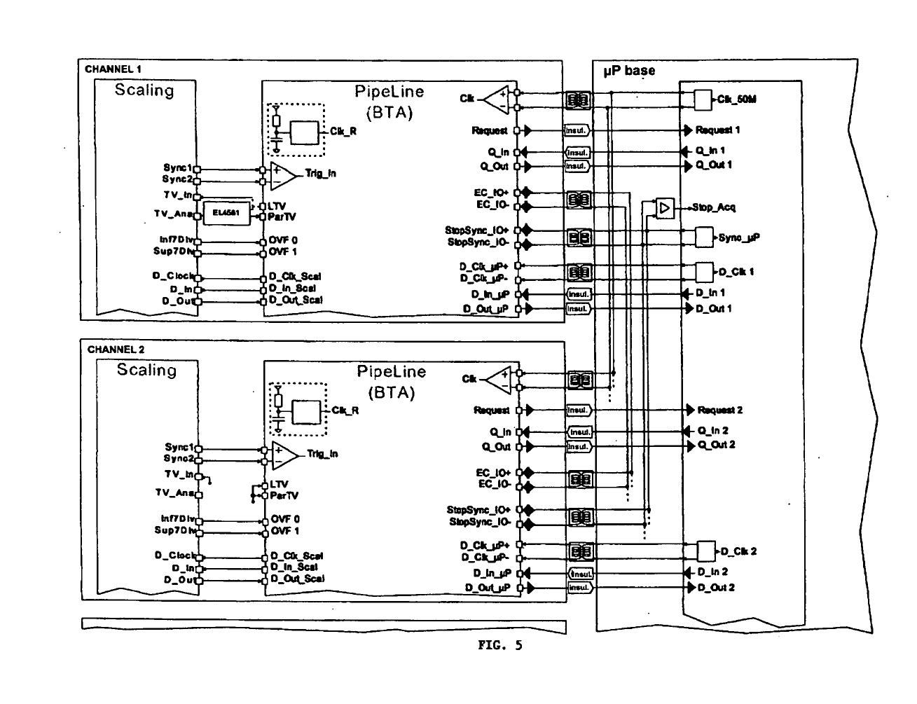

FIG. 5 shows the block diagram of the equipment, depicting the programming signals exchanged between the channels and the frame.

FIG. 1 shows the general architecture of an oscilloscope according to the invention. In this figure, the blocks (1 to 6) enclosed in a bold line correspond to the electronic circuits whose exposed conductive parts are insulated from the exposed conductive parts of the other circuits. It can be seen that there is therefore one exposed conductive part for the main circuit (1), one exposed conductive part per input channel (2 to 5) and one exposed conductive part for the communication channel (6). The exposed conductive part of the communication interface (6) is, when possible, grounded.

The main circuit (1) comprises the means that display the signals as well as the control means.

It comprises a circuit for processing the digital input data, made up of a processor (8) and a co-processor (7). The co-processor (7) consists of an FPGA (Field Programmable Gate Array) reconfigurable VLSI high-integration component.

This main circuit (1) also comprises:

a screen driver (9)

graphics RAM (10)

a VGA graphics module (11)

interface modules for the memory (12) and sound (14), a communication driver (15) and a keyboard (16)

a wireless communication module (17) using the BLUETOOTH protocol

a circuit with an RS232 and ETHERNET interface (18).

The power supply is designed so as to respect the galvanic insulation required for each circuit.

For this purpose, the main circuit (1) comprises a set of batteries (20) and a power supply circuit (60) supplying the various direct and alternating current voltages required for the operation of the various circuits. Each channel (2 to 5) comprises a transformer (21, 31, 41, 51) associated with a rectifier circuit and a voltage regulator.

The first of all the channel transformers (21, 31, 41, 51) is supplied by an H-bridge clipper by means of respective insulation circuits (25, 35, 45, 55).

The circuits (2 to 5) of each channel comprise a digital input (22, 32, 42, 52) receiving the signal coming from the analogue-to-digital converter of the relevant channel, as well an integrated circuit (23, 33, 43, 53) performing the scaling processes of the signals and an integrated circuit (24, 34, 44, 54) providing memorizing and sequencing functions (time base, hold off, pre-trig, post-trig, photo-trig, vernier), grouped together under the term: acquisition machine.

Each input circuit (2 to 5) exchanges digital information with the main circuit (1) by means of a serial link of the bi-directional synchronous type. This link is insulated by means of an insulation circuit (26, 36, 46, 56). This exchanged digital information includes the sampled and digitized acquisition signals, which are transmitted from each of the channels to the main circuit, and are completed by digital service signals, which are transmitted by the card to one or several input circuits (2 to 5).

FIG. 2 shows a view of the input circuits (only three channels are shown).

In this example of an embodiment of the invention, each channel comprises:

an analogue-digital converter (27, 37, 47)

a trigger circuit (28, 38, 48)

a time base (29, 39, 49) delivering a specific clock signal to the relevant channel,

a digitisation and memorization circuit (24, 34, 44).

The synchronizing channel constitutes the master channel and the other channels are slave channels. The master channel can be any one of the channels (2 to 5), and this selection can be reconfigured by the user at any time. In order to obtain an accurate position of the reconstituted signals, the master channel must exchange signals with the slave channels.

The acquisition machine of the master channel is the one that controls the starting and stopping of the acquisition of all the channels when the logical conditions are met. (The recording depth is reached, etc.).

Each slave channel comprises in its acquisition machine a set of circuits that is identical to that of the master circuit but in slave configuration. This configuration limits the functions of the machine. Deactivation of the sequencing block (40 FIG. 2) and of the processing of the effective trigger (30 FIG. 2). The trigger filter block (10 FIG. 2) will be used in the case of multichannel triggering.

As an alternative, according to a variant embodiment shown in FIG. 3, a master time base 30 (FIG. 2) is implemented on the main circuit (1) and delivers a distributed clock signal CLK_Ech to the various channels (2 to 5).

The input machine shown in FIG. 4 in a preferred configuration manages all the digital signals required for the performance of an acquisition. The arrangement of the various functional blocks of the machine with regard to the insulation barrier of the channels, results in variants of the present invention that will be described below. According to the preferred configuration, all the blocks except block 100 “multichannel trigger logic” are duplicated as many times as there are channels in the final oscilloscope. This block 100 is centralized. It is in the electric potential of the frame.

FIG. 5 shows the block diagram of the equipment, depicting the programming signals exchanged between the channels and the frame:

D_CLOCK, clock of the serial link: Specific signal for each of the channels.

D_IN, data serialized to the channel: Specific signal for each of the channels.

D_OUT, data serialized from the channel to the frame: Specific signal for each of the channels.

The service signals exchanged between the channels and the frame are as follows:

CLK_REF, reference clock used to create the sampling clock or clocks CLK_Ech of each channel.

CLK_Ech, sampling clock created by the time base 100. This signal can either be centralized and distributed to the channels, or locally synthesized on the channels. In this case, the SYNC signal described below ensures the phasing of the various CLK_Ech clocks.

REQUEST, interruption signal from the channel to the central unit. Specific signal for each of the channels.

STOP_SYNC, multiplexed line shared by all the channels and the FPGA. It can equally transmit the STOP signal or the SYNC synchronization cue for the time bases of the channels when they are delocalised in the channels. Bidirectional signal.

Q_IN, qualifier or Auxiliary Trigger: signal sent from the Multichannel Trigger Logic block to the master channel. Optional.

Q_OUT, qualifier or Filtered Trigger: signal sent from the Trigger Filtering block 10 to the Multichannel Trigger Logic block. Specific signal for each of the channels. Optional.

EC_IO, signal shared by all the channels, bidirectional, allowing the end-of-counting signalisation for the trig after count triggers. Optional.

ALIM, power supply circuit of the channels by means of alternating current and transformers.

The performance of a quick acquisition (too fast for the samples to be transferred in real time to the central unit) implements the following steps:

Preparation:

The CLK_REF clock being previously established on the channels, the central unit programmes the required time base over the serial link and configures, if necessary, all the channel registries: vertical rating, source and level of the trigger, coupling, voltage difference, etc.

The central unit sends a synchronization pulse SYNC to the channels via the FPGA over the STOP_SYNC line. This pulse allows the temporary setting of the time base counters that are specific to each channel. The processor must also program the master channel, that is to say, the channel that is sensitive to the trigger. This channel synchronizes the acquisition of the other channels via the STOP signal. These two signals are transmitted over the same physical link STOP_SYNC.

Waiting for the Trigger:

The central unit orders the start by means of a specific command over the serial link, the acquisition begins, and the countdown of the pretrig is performed. At the end of the pretrig, the master channel becomes sensitive to the trigger.

Trigger:

The first trigger pulse edge causes the master channel to switch into counting the postrig. The dating of the Trigger with regard to the samples is assured by the Photo-Trig and Vernier blocks.

Stop:

At the end of the postrig, the master channel emits a stop over the STOP_SYNC line. The stop is emitted by the master channel to itself and all the slave channels (one in the case of FIG. 1), and at this time the acquisition is ended on all the master and slave channels.

Dumping:

The dumping operation is orchestrated by the FPGA circuit and consists of transferring all the samples acquired to the working memory of the central unit over the serial link. To do so, the FPGA which controls the serial links of the channels proceeds by DMA on the memory of the central unit.

Display:

The display is carried out based on the information contained in the samples transferred with the help of an adapted algorithm.

The process of a slow acquisition (the acquired samples are transferred immediately to the processor memory) is described below:

Preparation:

The central unit configures all the channel registers: vertical rating, source and level of the trigger, voltage difference, etc.

The FPGA assures the rate of sampling. The reading of the current sample causes the sampling of the next sample. In this mode, the acquisition machines of each channel generate the sampling clock CLK_Ech from sample reading rasters emitted by the FPGA. The time base counters of the channels are not used. The same applies to the photo-trig and vernier.

Waiting for the Trigger:

The central unit orders the start by means of a specific command over the serial link, the acquisition begins, and the countdown of the pretrig is performed. At the end of the pretrig, the master channel becomes sensitive to the trigger.

Trigger:

The first trigger pulse edge causes the master channel to switch into counting the postrig and creates a REQUEST. At the end of the postrig, the master channel emits a STOP over the STOP_SYNC line.

Stop:

The STOP is emitted by the master channel to itself and all the slave channels as well as to the FPGA of the frame; at this time the acquisition is ended on all the master and slave channels.

Display:

The display is carried out based on the information contained in the samples transferred with the help of an adapted algorithm.

1. A multi-channel digital oscilloscope, comprising a plurality of analog inputs, circuits for analogue processing of input signals, sampling circuits, digitization circuits, trigger means and means for synchronising various channels and electrical insulation means, wherein, for N channels, N being greater than 1 and at most equal to the total number of channels, at least the sampling and digitization circuits are situated between the analogue input and the insulation means, and further comprising a buffer for storing signals between the analog input and the insulation means.

2. A digital oscilloscope according to claim 1, further comprising means for resynchronization of traces corresponding to the input signals comprising a master acquisition machine controlling each of the acquisition machines of the sampling circuits of each of the channels.

3. A digital oscilloscope according to claim 2, characterised in that said master acquisition machine is the acquisition machine of one of the channels.

4. A digital oscilloscope according to claim 2, characterised in that said master acquisition machine comprises a main time base delivering a distributed time signal to each channel.

5. A digital oscilloscope according to claim 4, characterised in that said main time base is located after the insulation means.

6. A digital oscilloscope according to claim 1, characterised in that said insulation means are made up of a transformer.

7. A digital oscilloscope according to claim 6, characterised in that said transformer comprises common mode rejection means.

8. A digital oscilloscope according to claim 7, characterised in that said common mode rejection means are electromagnetic shielding.

9. A digital oscilloscope according to claim 7, characterised in that said common mode rejection means are a winding with a midpoint.

10. A digital oscilloscope according to claim 1, characterised in that said insulation means comprise an optocoupler.

11. A digital oscilloscope according to claim 1, characterised in that said insulation means comprise a radio transceiver.

12. A digital oscilloscope according to claim 1, characterised in that at least a part of the data exchanged between a frame and the channels is multiplexed.

13. A digital oscilloscope according to claim 2, characterised in that at least two channels comprise sampling and digitization circuits made up of a time base, a threshold trigger circuit supplying the acquisition machine with a pulse edge that corresponds to the input signal passing a trigger threshold.

14. A digital oscilloscope according to claim 1, characterised in that said buffer is an analog memory located between the sampling circuit and the digitization circuit.

15. A digital oscilloscope according to claim 1, characterised in that said buffer is a digital memory located between the digitization circuit and the insulation means.

16. A digital oscilloscope according to claim 1, characterised in that each channel comprises a circuit for identifying and memorizing a clock period that corresponds to the trigger, supplying digital identification information transmitted with the signal samples of the relevant channel.

17. A digital oscilloscope according to claim 1, further comprising, for each channel, a vernier circuit made up of a ramp generator performing a linear “time difference/voltage difference” conversation in order to supply information that is representative of the time interval between the trigger pulse edge and the clock front edge, said information being digitized and transmitted with the signal samples of the relevant channel.

18. A digital oscilloscope according to claim 2, further comprising resynchronization means receiving conditional information from at least one channel to supply a start cue to the master acquisition machine.

19. A digital oscilloscope according to claim 18, characterised in that the slave acquisition machines control the sampling while waiting for the signal to end acquisition from the master acquisition machine.

20. A digital oscilloscope according to claim 1, further comprising an independent power supply for each channel which is insulated and adjusted for supplying the circuits located upstream from the insulation means.

21. A digital oscilloscope according to claim 2, further comprising a processor that controls the configuration of the circuits and acquisition machines according to settings chosen by the user, assuring the processing of the data of each channel as well as the service information, in order to calculate a graphic representation according to the signals acquired on the various channels.

22. A digital oscilloscope according to claim 1, characterised in that each channel comprises a transformer associated with a rectifier circuit and a voltage regulator.

23. A digital oscilloscope according to claim 1, characterised in that a photo trig circuit is located on a frame.

24. A digital oscilloscope according to claim 1, characterised in that a vernier is located on a frame.
